(19) United States
(12) Patent Application Publication
(10) Pub. No.: US 2016/0079382 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Masaaki OGAWA, Sagamihara Kanagawa (JP); Takako MOTAI, Yokohama Kanagawa (JP)

(21) Appl. No.: 14/635,327

(22) Filed: Mar. 2, 2015

(30) Foreign Application Priority Data
Sep. 16, 2014 (JP) 2014-187204

(51) Int. Cl. H01L 29/49; H01L 21/28; H01L 29/778; H01L 29/51

(52) U.S. Cl. CPC H01L 29/4966; H01L 29/517; H01L 29/518; H01L 21/28088; H01L 29/778

(57) ABSTRACT

A semiconductor device includes a semiconductor layer, a gate insulation film on the semiconductor layer, and a gate electrode on the gate insulation film. The gate electrode includes a first metal compound layer with a first element also contained in the gate insulation film. A first metal layer is on the first metal compound layer, wherein the diffusion coefficient thereof in gold is smaller than the diffusion coefficient thereof in nickel. The first metal layer includes a second element also contained in the first metal compound layer. A gold layer is on the first metal layer. A second metal layer is on the gold layer. Third metal layers are on side surfaces of the gold layer. A source and drain electrode are provided. An interlayer insulation film is on the gate electrode.

### CROSS-REFERENCE TO RELATED APPLICATION

This application is based upon and claims the benefit of priority from Japanese Patent Application No. 2014-187204, filed Sep. 16, 2014, the entire contents of which are incorporated herein by reference.

### FIELD

Embodiments described herein relate generally to a semiconductor device.

### BACKGROUND

In integrated circuits such as a switching power supplies and inverters, a power semiconductor element such as a switching element and a diode are used. These power semiconductor elements require high withstand voltage and low ON resistance. The withstand voltage and the ON resistance are trade-off design features based on the semiconductor material of the device.

According to the progress in the development of this technology up to now, in a power semiconductor element, the low ON resistance that is realized is close to the limit of silicon, which is a main element material. In order to further decrease the ON resistance, the basic semiconductor material has to be changed. It is possible that the design trade-off between high withstand voltage and low ON resistance is lessened by using a GaN-based semiconductor such as GaN and AlGaN, or a wide band gap semiconductor such as silicon carbide (SiC) as a switching element material.

Among devices using the GaN-based semiconductor such as GaN and AlGaN, as a device element that can easily obtain the low ON resistance, for example, a high electron mobility transistor (HEMT) using an AlGaN/GaN hetero structure is included. The HEMT realizes low ON resistance by the high electron mobility of a hetero interface channel and high electron concentration generated by polarization. Accordingly, low ON resistance is obtained even if the chip area of the element is small.

As one structure of the HEMT, there is a MIS-type HEMT including a metal insulator semiconductor (MIS) structure. In the MIS-type HEMT, metal that forms the gate electrode is diffused into the gate insulation film or into the interlayer insulation film, which causes poor reliability of the resulting HEMT.

### DESCRIPTION OF THE DRAWINGS

FIGS. 1A and 1B are diagrams schematically illustrating a cross section of a semiconductor device according to a first embodiment.

FIG. 2 is a photograph showing the cross section of a semiconductor device according to a comparative embodiment.

FIG. 3 is a photograph showing the cross section of a semiconductor device according to the comparative embodiment.

FIG. 4 is a photograph showing a cross section of the semiconductor device according to a comparative embodiment.

FIG. 5 is a photograph showing a cross section of a semiconductor device according to the comparative embodiment.

FIG. 6 is a photograph showing a cross section of a semiconductor device according to the first embodiment.

FIG. 7 is a diagram schematically illustrating a cross section of a semiconductor device according to a second embodiment.

### DETAILED DESCRIPTION

An exemplary embodiment is to provide a semiconductor device having enhanced reliability.

In general, according to one embodiment, there is provided a semiconductor device including a semiconductor layer. A gate insulation film is provided on the semiconductor layer. A gate electrode is provided on the gate insulation film and includes a first metal compound layer that includes a first element that is also contained in the gate insulation film. A first metal layer is provided on the first metal compound layer. A diffusion coefficient of metal in the metal layer in gold (Au) is smaller than that in nickel (Ni), and includes a second element also contained in the first metal compound layer. A gold (Au) layer is provided on the first metal layer. A second metal layer is provided on the gold layer. And third metal layers are provided on side surfaces of the gold layer. A source electrode is provided, for example, on the semiconductor layer. A drain electrode is provided, for example, on the semiconductor layer so that the gate electrode is interposed between the drain electrode and the source electrode in some embodiments. An interlayer insulation film is provided over the second metal layer and the third metal layers on the gate electrode.

In the specification, the same or similar elements of the described device are denoted by the same reference numerals, and repetitive descriptions thereof may be omitted as appropriate.

In the specification, a “GaN-based semiconductor” generically refers to a semiconductor including GaN (gallium nitride), AlN (aluminum nitride), and InN (indium nitride), and an intermediate composition thereof.

In the specification, a “non-doped” state refers to a state in which dopants are not intentionally introduced into the material, and the concentration of dopants is generally equal to or less than 1×10¹⁵ cm⁻³.

In addition, in the specification, the terms “upper” and “lower” indicate relative positional relationships of configuration elements, and do not necessarily coincide with a direction respect to the gravity direction.

### First Embodiment

A semiconductor device according to the first embodiment includes a GaN-based semiconductor layer; a gate insulation film provided on the GaN-based semiconductor layer; a gate electrode including a first metal compound layer which is provided on the gate insulation film and includes a first element also contained in the gate insulation film, a first metal layer which is provided on the first metal compound layer, of which a diffusion coefficient in gold (Au) is smaller than that in nickel (Ni), and includes a second element also contained in the first metal compound layer, a gold (Au) layer provided on the first metal layer, a second metal layer provided on the gold layer, and third metal layers provided on side surfaces of the gold layer; a source electrode provided on the GaN-based semiconductor layer; a drain electrode provided on the GaN-based semiconductor layer so that the gate electrode is interposed between the drain electrode and the source electrode; and an interlayer insulation film provided on the gate electrode.

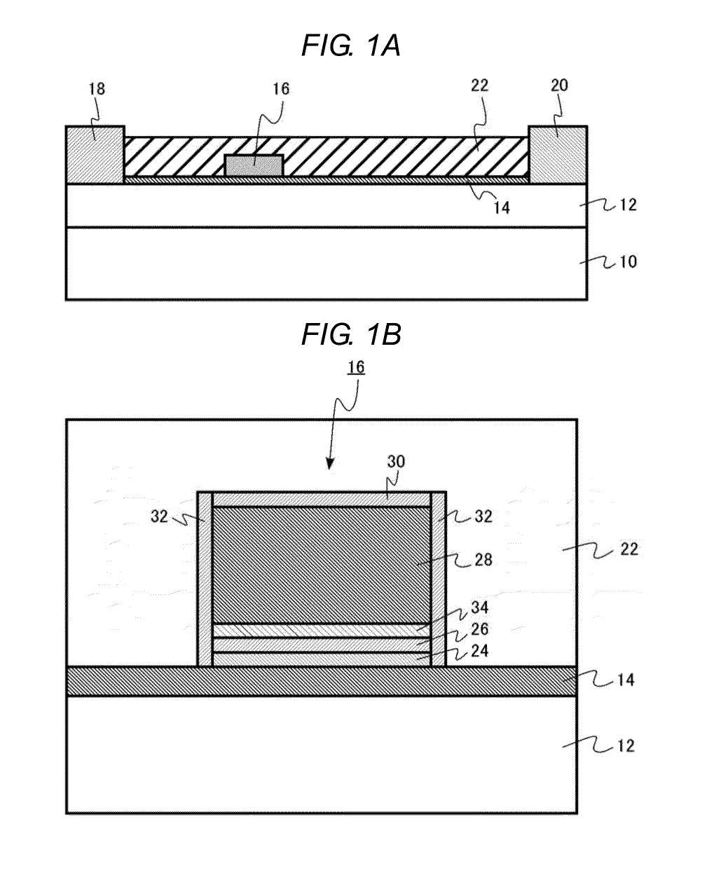

FIGS. 1A and 1B are cross-sectional views schematically illustrating a cross section of a semiconductor device according to the first embodiment. The semiconductor device according to the first embodiment is a MIS-type HEMT of the GaN-based semiconductor. FIG. 1A is a cross-sectional view schematically illustrating a transistor, and FIG. 1B is a diagram illustrating the layered structure of the gate electrode of FIG. 1A.

As illustrated in FIG. 1A, in the semiconductor device according to the first embodiment, a barrier layer (GaN-based semiconductor layer) 12 of the GaN-based semiconductor having a greater band gap than that of a channel layer 10 on the channel layer 10 of the GaN-based semiconductor. In addition, the gate insulation film 14 is provided on the barrier layer 12.

A gate electrode 16 is provided on a gate insulation film 14. A source electrode 18 is provided on the barrier layer 12. A drain electrode 20 is provided on the barrier layer 12 so that the gate electrode 16 is interposed between the drain electrode 20 and the source electrode 18. An interlayer insulation film 22 is provided on the gate electrode 16.

For example, the channel layer 10 is, for example, non-doped AlₓGa₁₋ₓN (0≦X<1). For example, the channel layer 10 is non-doped GaN. Further, n-type or p-type impurities may be contained in the channel layer 10.

The barrier layer 12 is, for example, non-doped or n-type Al_{y}G_{a1-Y}N (0<Y≦1 and X<Y). The barrier layer 12 is, for example, non-doped Al_{0.25}Ga_{0.75}N. The barrier layer 12 has higher aluminum (Al) concentration than that of the channel layer 10.

The gate insulation film 14 is, for example, a silicon nitride film. As the gate insulation film 14, for example, a silicon oxide film or a silicon oxynitride film also may be used.

As illustrated in FIG. 1B, the gate electrode 16 includes a first metal compound layer 24 on the gate insulation film 14, a first metal layer 26 on the first metal compound layer 24, a gold (Au) layer 28 on the first metal layer 26, a second metal layer 30 on the gold layer 28, and third metal layers 32 on side surfaces of the gold layer 28. Further, a fourth metal layer 34 is provided between the first metal layer 26 and the gold layer 28. The metal and metal compound layers 24, 26, 30, 32 and 34 provide diffusion barrier layers for limiting diffusion of the gold layer 28 into adjacent insulator layers, and help increase adhesion of the gold to adjacent film layer materials.

The first metal compound layer 24 includes a first element also contained in the gate insulation film 14. The first metal layer 26 includes a second element of which a diffusion coefficient thereof in gold (Au) is smaller than that in nickel (Ni), and which is also contained in the first metal compound layer 24.

The first metal compound layer 24 and the first metal layer 26 have a function of suppressing gold (Au) diffusion into the gate insulation film 14 or the barrier layer 12. The first metal compound layer 24 and the first metal layer 26 function as so-called barrier metal.

For example, the gate insulation film 14 is a silicon nitride film, the first metal compound layer 24 is titanium nitride, and the first metal layer 26 is titanium (Ti). In this case, the first element is nitrogen (N), and the second element is titanium (Ti).

Also, for example, the gate insulation film 14 is a silicon oxide film, the first metal compound layer 24 is titanium oxide, and the first metal layer 26 is titanium (Ti). In this case, the first element is oxygen (O), and the second element is titanium (Ti).

In addition, for example, the gate insulation film 14 is a silicon oxide film, the first metal compound layer 24 is titanium silicide, and the first metal layer 26 is titanium (Ti). In this case, the first element is silicon (Si), and the second element is titanium (Ti).

The first metal compound layer 24 is desirably a metal compound formed by the reaction between the gate insulation film 14 and the first metal layer 26.

The second metal layer 30 has a function of suppressing gold (Au) diffusion into the interlayer insulation film 22. The second metal layer 30 functions as so-called barrier metal. In addition, the second metal layer 30 has a function of enhancing the adhesive properties between the gate electrode 16 and the interlayer insulation film 22.

The second metal layer 30 is, for example, titanium (Ti). In addition, as the second metal layer 30, tantalum (Ta), tungsten (W), or molybdenum (Mo) may be applied. The second metal layer 30 is desirably a material that causes the metal compound to be produced by the reaction with the material of the interlayer insulation film 22.

The third metal layer 32 has a function of suppressing gold (Au) diffusion into the interlayer insulation film 22. The third metal layer 32 functions as so-called barrier metal. In addition, the third metal layer 32 has a function of enhancing the adhesive properties between the gate electrode 16 and the interlayer insulation film 22.

The third metal layer 32 is, for example, titanium (Ti). In addition, as the third metal layer 32, tantalum (Ta), tungsten (W) or molybdenum (Mo) may be applied. The third metal layer 32 is desirably a material that causes a metal compound to be produced by the reaction with the material of the interlayer insulation film 22.

The second metal layer 30 and the third metal layer 32 are preferably formed of the same material for obtaining a continuous film thereof. In addition, the first metal layer 26, the second metal layer 30, and the third metal layer 32 are preferably formed of the same material.

The alternatively provided fourth metal layer 34 is formed with a material different from that of the first metal layer 26. The fourth metal layer 34 has a function of suppressing gold (Au) diffusion into the gate insulation film 14 or the barrier layer 12. The fourth metal layer 34 functions as so-called barrier metal.

The fourth metal layer 34 is, for example, platinum (Pt). In addition, as the fourth metal layer 34, metal such as tungsten (W) and titanium (Ti), metal nitride such as tungsten nitride (WN) and titanium nitride (TiN), and conductive metal oxide such as indium tin oxide (ITO) and zinc oxide (ZnO) may be applied.

The source electrode 18 and the drain electrode 20 are metal electrodes. The materials of the source electrode 18 and the drain electrode 20 may include, for example, titanium (Ti), titanium nitride (TiN), aluminum (Al), tantalum (Ta), molybdenum (Mo), or tungsten (W). The source electrode 18 and the drain electrode 20 may be stacked structures of a plurality of kinds of metal. Ohmic contacts are desirably formed between the source electrode 18 and the barrier layer 12 and between the drain electrode 20 and the barrier layer 12.

The interlayer insulation film 22 is, for example, a silicon nitride film. As the interlayer insulation film 22, for example, a silicon oxide film or a silicon oxynitride film may be applied.

Next, actions and effects of the semiconductor device according to the first embodiment are described.

In the MIS-type HEMT, in view of the desire to realize a highly reliable transistor having high-performance, the material of the gate electrode is selected. In view of the stability of the gate electrode and the decrease of the resistance, gold (Au) is desirably selected as a material.

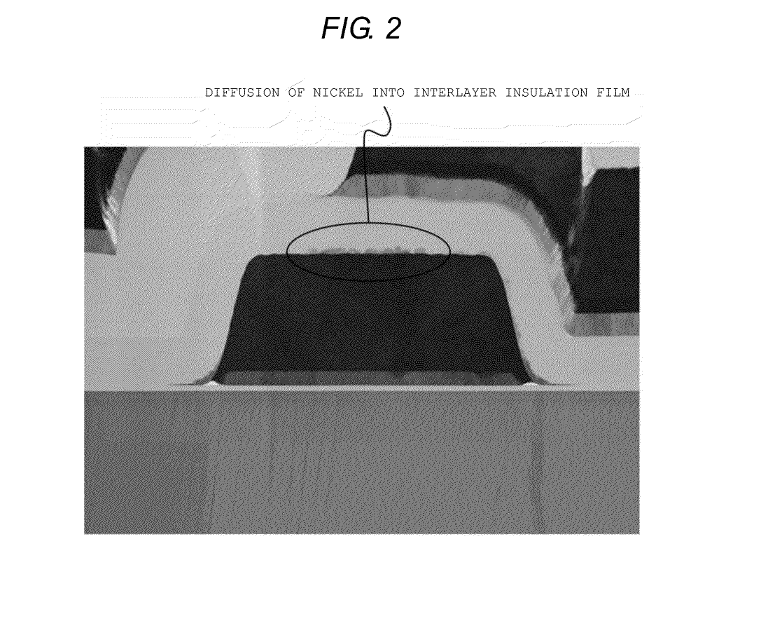

FIGS. 2 to 5 are pictures showing cross sections of a semiconductor device according to a comparative embodiment. The semiconductor device according to the comparative embodiment is a MIS-type HEMT. A gate electrode of the MIS-type HEMT according to the comparative embodiment has a stacked structure of a nickel (Ni) layer and a gold (Au) layer starting from a gate insulation film side, i.e., the nickel layer contacts the gate insulation film and the gold layer is formed thereover. The gate insulation film is a silicon nitride film, and an interlayer insulation film is a silicon nitride film.

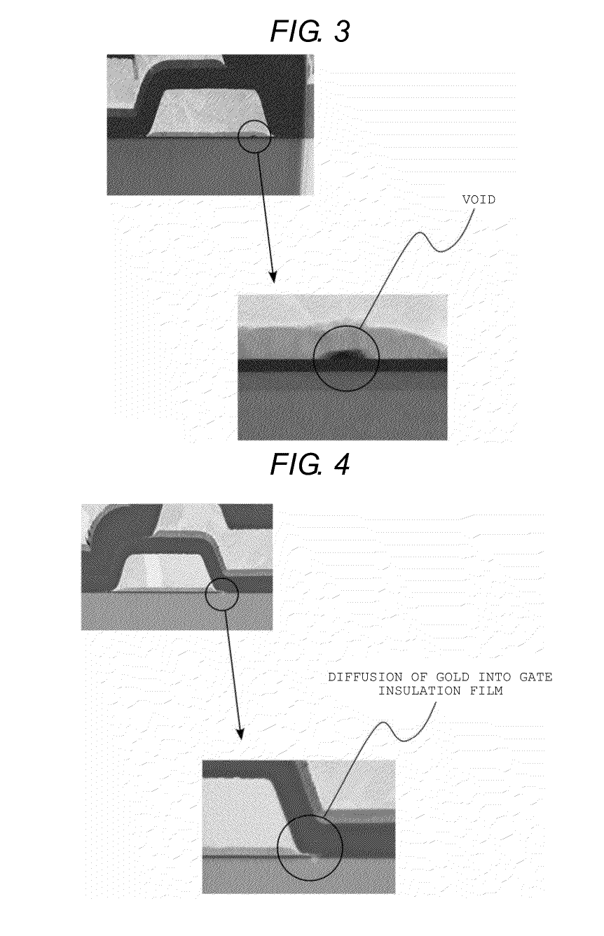

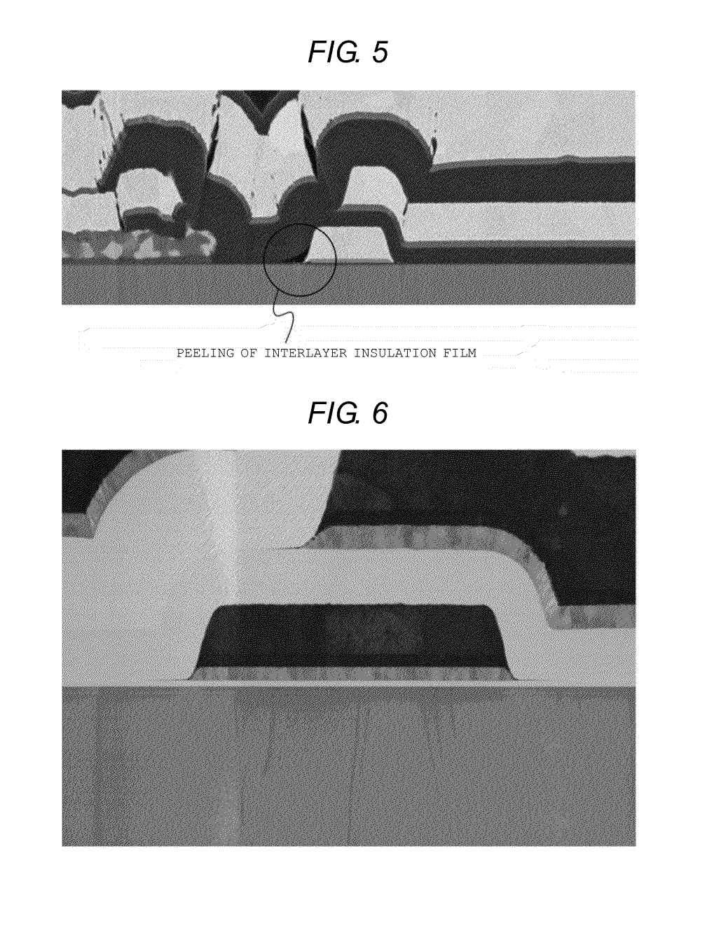

In the MIS-type HEMT according to the comparative embodiment, nickel diffused into and through the gold layer is diffused into the interlayer insulation film on an upper portion of the gate electrode (FIG. 2). In addition, nickel in the nickel layer is removed therefrom by diffusion, and void is generated in the nickel layer (FIG. 3). The diffusion of gold (Au) into the gate insulation film occurs (FIG. 4). Further, the adhesive properties between the gold layer exposed on the gate electrode side and the interlayer insulation film are poor and a cavity caused by the peeling of the interlayer insulation film by the side of the gate electrode is formed (FIG. 5).

It is found that the phenomena observed in FIGS. 2 to 5 become main causes of poor reliability of the MIS-type HEMT according to the comparative embodiment.

In the semiconductor device according to the first embodiment, the first metal layer 26 is formed of a material including a second element of which the diffusion coefficient thereof in gold (Au) is smaller than that in nickel (Ni), for example titanium (Ti). Accordingly, the diffusion of the element that configures the first metal layer 26 is suppressed, and for example, the diffusion of the element into the interlayer insulation film 22 and the generation of the void as illustrated in FIGS. 2 and 3 are suppressed.

In addition, the diffusion of gold (Au) into the gate insulation film is suppressed by providing the first metal compound layer 24 between the gate insulation film 14 and metal as barrier metal. Further, according to the first embodiment, the diffusion of gold (Au) into the gate insulation film is further suppressed by providing the fourth metal layer 34 between the gate insulation film 14 and the metal 28 as barrier metal. Accordingly, the diffusion of gold (Au) into the gate insulation film as illustrated in FIG. 4 is suppressed.

In addition, the direct contact between the gold layer 28 and the interlayer insulation film 22 is prevented by providing the third metal layer 32 on the side surface of the gold layer 28. Accordingly, the adhesive properties between the gate electrode 16 and the interlayer insulation film 22 are enhanced. Therefore, as illustrated in FIG. 5, the formation of a cavity caused by the peeling of the interlayer insulation film is suppressed. In addition, in view of the enhancement of the adhesive properties between the gate electrode 16 and the interlayer insulation film 22, the third metal layer 32 is desirably a material that causes a metal compound such as an oxide and a silicide to be produced by the reaction with the material of the interlayer insulation film 22.

Further, the first metal compound layer 24 is a material that includes a first element also contained in the gate insulation film 14. Also, the first metal layer 26 includes a second element also contained in the first metal compound layer 24. According to the configuration, the adhesive properties between the gate insulation film 14 and the gate electrode 16 are enhanced.

In view of the enhancement of the adhesive properties between the gate insulation film 14 and the gate electrode 16, the first metal compound layer 24 is desirably a metal compound such as an oxide and a silicide formed by the reaction between the gate insulation film 14 and the first metal layer 26. For example, when the gate insulation film 14 is a silicon nitride film, the first metal compound layer 24 which is titanium nitride is desirably formed by depositing titanium in the gate insulation film 14 as the first metal layer 26 and then causing the titanium to react while heated during an annealing step to form the silicide.

In addition, direct contact between the gold layer 28 and the interlayer insulation film 22 is prevented by providing the second metal layer 30 on the upper surface of the gold layer 28. Accordingly, the adhesive properties between the gate electrode 16 and the interlayer insulation film 22 are enhanced. In addition, in view of the enhancement of the adhesive properties between the gate electrode 16 and the interlayer insulation film 22, the second metal layer 30 is desirably a material that causes the metal compound such as an oxide and a silicide to be produced by the reaction thereof with the material of the interlayer insulation film 22.

In view of the decrease of the manufacturing cost, the second metal layer 30 and the third metal layer 32 are preferably formed of the same material in order to obtain a continuous film composed of the second metal layer 30 and the third metal layer 32. Also, in the same manner, in view of the decrease of the manufacturing cost, the first metal layer 26, the second metal layer 30, and the third metal layer 32 are preferably formed of the same material.

FIG. 6 is a picture showing a cross section of the semiconductor device according to the first embodiment. In the MIS-type HEMT according to the first embodiment, the gate electrode 16 is configured with a titanium nitride layer of the first metal compound layer 24, a titanium layer of the first metal layer 26, a platinum layer of the fourth metal layer 34, the gold layer 28, a titanium layer of the second metal layer 30, and a titanium layer which is the third metal layer 32 on the side surface of the gold layer 28 as is shown in FIG. 1B. The second metal layer 30 and the third metal layer 32 are continuous films. The gate insulation film is a silicon nitride film, and the interlayer insulation film is a silicon nitride film.

As clearly seen in FIG. 6, the phenomena observed in the comparative embodiment as illustrated in FIGS. 2 to 5 are not observed in the first embodiment. Also, compared with the comparative embodiment, it is confirmed that poor reliability derived from migration and delamination issues are decreased.

As described above, according to the first embodiment, when nickel is used as the gate electrode material, a problem caused by the diffusion of nickel can be solved. In addition, even when gold is used as the gate electrode material, problems caused by the diffusion of gold, and of the barrier metal through the gold, can be solved, and the adhesion of the interlayer insulation film to the gate electrode can be improved. Accordingly, the semiconductor device in which reliability is increased is realized.

### Second Embodiment

A semiconductor device according to the second embodiment is the same as the semiconductor device according to the first embodiment except that the semiconductor device according to the second embodiment further includes a second metal compound layer which is provided between the second metal layer and the interlayer insulation film and includes elements also contained respectively in the second metal layer and the interlayer insulation film; and a third metal compound layer which is provided between the third metal layer and the interlayer insulation film, and includes elements commonly contained respectively in the third metal layer and the interlayer insulation film. Accordingly, matters overlapped with the first embodiment are omitted in the description.

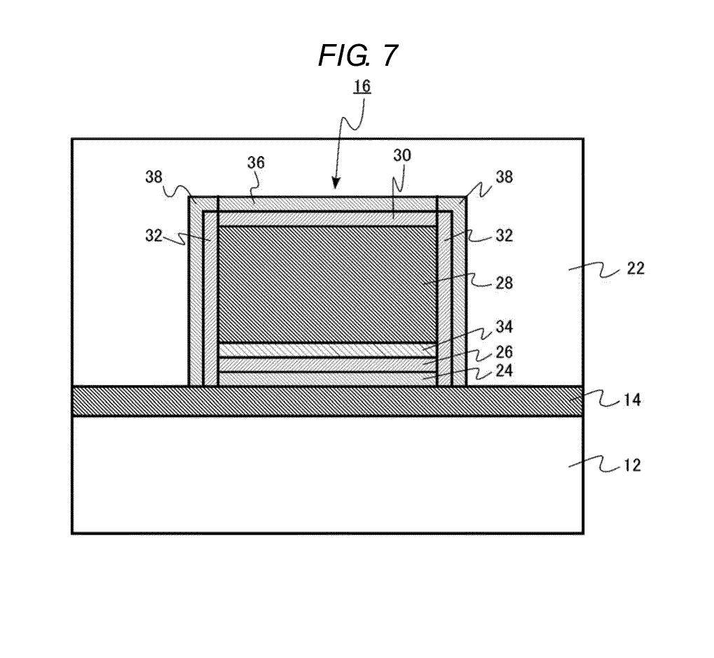

FIG. 7 is a cross-sectional view schematically illustrating the semiconductor device according to the second embodiment.

As illustrated in FIG. 7, the gate electrode 16 includes a second metal compound layer 36 between the second metal layer 30 and the interlayer insulation film 22. In addition, a third metal compound layer 38 is provided between the third metal layer 32 and the interlayer insulation film 22.

The second metal compound layer 36 includes elements also contained respectively in the second metal layer 30 and the interlayer insulation film 22. For example, the second metal layer 30 is titanium, and the second metal compound layer 36 is titanium nitride, and the interlayer insulation film 22 is a silicon nitride film. In this case, the element also contained in the second metal layer 30 is titanium (Ti), and the element also contained in the interlayer insulation film 22 is nitrogen (N). Also, for example, the second metal layer 30 is titanium, the second metal compound layer 36 is titanium oxide, and the interlayer insulation film 22 is a silicon oxide film. In this case, the element also contained in the second metal layer 30 is titanium (Ti), and the element also contained in the interlayer insulation film 22 is oxygen (O).

The third metal compound layer 38 includes elements also contained respectively in the third metal layer 32 and the interlayer insulation film 22. For example, the third metal layer 32 is titanium, the third metal compound layer 38 is titanium nitride, and the interlayer insulation film 22 is a silicon nitride film. In this case, the element also contained in the third metal layer 32 is titanium (Ti), and the element also contained in the interlayer insulation film 22 is nitrogen (N). In addition, for example, the third metal layer 32 is titanium, the third metal compound layer 38 is titanium oxide, and the interlayer insulation film 22 is a silicon oxide film. In this case, the element also contained in the third metal layer 32 is titanium (Ti), and the element also contained in the interlayer insulation film 22 is oxygen (O).

The MIS-type HEMT according to the second embodiment includes the second metal compound layer 36 and the third metal compound layer 38, and has improved adhesive properties between the gate electrode 16 and the interlayer insulation film 22 compared with the first embodiment.

In view of the improvement of the adhesive properties between the gate electrode 16 and the interlayer insulation film 22, the second metal compound layer 36 is desirably a metal compound such as an oxide and a silicide formed by the reaction between the second metal layer 30 and the interlayer insulation film 22. For example, when the second metal layer 30 is titanium, the second metal compound layer 36 which is titanium nitride is desirably formed by depositing a silicon nitride film on the gate electrode 16 as the interlayer insulation film 22 and then causing the silicon nitride film to react by a heat process.

In the same manner, in view of the improvement of the adhesive properties between the gate electrode 16 and the interlayer insulation film 22, the third metal compound layer 38 is desirably a metal compound such as a nitride, an oxide or a silicide formed by the reaction between the third metal layer 32 and the interlayer insulation film 22. For example, when the third metal layer 32 is titanium, the third metal compound layer 38 which is titanium nitride is preferably formed by depositing a silicon nitride film on the gate electrode 16 as the interlayer insulation film 22 and then causing the silicon nitride film to react with the titanium film layer by a heat process to form titanium nitride.

According to the embodiment, an example in which GaN or AlGaN is used as the material of the semiconductor layer, but, for example, InGaN, InAlN, and InAlGaN containing indium (In) may be applied. In addition, AlN may be applied as the material of the semiconductor layer.

In the embodiment, as the barrier layer, non-doped AlGaN is described as an example, but n-type AlGaN may be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer;
a gate insulation film disposed on the semiconductor layer;
agate electrode, including a first metal compound layer comprising a first metal element also included in the gate insulation film, located on the gate insulation film, a first metal layer, the diffusion coefficient of the metal of the metal layer in gold is smaller than the diffusion coefficient thereof in nickel, and comprising a second metal element also present in the first metal compound layer, located on the first metal compound layer, a gold (Au) layer provided on the first metal layer, a second metal layer provided on the gold layer, and third metal layers provided on side surfaces of the gold layer;
a source electrode;
a drain electrode; and
an interlayer insulation film located over the second metal layer and the third metal layers on the gate electrode.

2. The device according to claim 1, wherein the drain electrode extends through the interlayer insulating film and into contact with the semiconductor layer.

3. The device according to claim 2, wherein the source electrode extends through the interlayer insulating film and into contact with the semiconductor layer, the gate electrode interposed between the source electrode and the drain electrode.

4. The device according to claim 1,
wherein the second metal layer and the third metal layer are formed of the same material and form a continuous film layer.

5. The device according to claim 4,
wherein the first metal layer, the second metal layer, and the third metal layer are formed of the same material.

6. The device according to claim 1, further comprising:
a second metal compound layer disposed between the second metal layer and the interlayer insulation film and comprising an element contained in the second metal layer and in the interlayer insulation film; and
a third metal compound layer located between the third metal layer and the interlayer insulation film and comprising an element contained in the third metal layer and in the interlayer insulation film.

7. The device according to claim 6, further comprising:
a fourth metal layer located between the first metal layer and the gold layer and comprising a different material than the material of the first metal layer.

8. The device according to claim 1,
wherein the gate insulation film comprises at least one of a silicon nitride film, a silicon oxide film, and a silicon oxynitride film.

9. The device according to claim 1,
wherein the interlayer insulation film comprises at least one of a silicon nitride film, a silicon oxide film, and a silicon oxynitride film.

10. The device according to claim 1,
wherein the first metal compound layer comprises titanium nitride, the first metal layer comprises titanium (Ti), the second metal layer is titanium (Ti), and the third metal layer comprises titanium (Ti).

11. The device according to claim 7,
wherein the fourth metal layer comprises platinum (Pt).

12. The device according to claim 7,
wherein the gate insulation film comprises a silicon nitride film, the first metal compound layer comprises titanium nitride, the first metal layer comprises titanium (Ti), the second metal layer comprises titanium (Ti), the third metal layer comprises titanium (Ti), the fourth metal layer comprises platinum (Pt), and the interlayer insulation film comprises a silicon nitride film.

13. A method of forming an electrode comprising gold on a first insulator film on a semiconductor device; comprising;
providing a first barrier layer comprising an element of the a first insulating film and a metal element on the first insulating film;
providing a second barrier layer comprising metal on the first barrier film, the second barrier film further comprising an element of the first barrier film, wherein the diffusion coefficient of the metal of the second barrier layer in gold is smaller than the diffusion coefficient thereof in nickel.

14. The method of claim 13, further comprising depositing a metal comprising the second barrier layer directly on the first insulator film; and
heating the first second barrier layer material and the first insulator film and thereby react a metal element of the second barrier film with an element of the first insulator film and form the first barrier layer between the second barrier layer and the first insulator layer.

15. The method of claim 14, wherein the metal element of the second barrier layer comprises titanium, and the element of the first insulator film comprises one of silicon, oxygen and nitrogen.

16. The method of claim 15, further comprising covering the electrode comprising gold and the first and second barrier layers in a third barrier layer comprising a metal.

17. A conductor structure on an insulator layer in a semiconductor, comprising:
a first barrier layer comprising at least an element of the insulator layer and a first metal disposed on the insulator layer;
a second barrier layer comprising the first metal; and
a gold layer disposed over the second barrier layer, wherein
the diffusion coefficient of the first metal in gold is smaller than the diffusion coefficient of the first metal in nickel.

18. The conductor structure of claim 17, wherein the first metal is titanium.

19. The conductor structure of claim 17, wherein the first barrier layer comprises at least one of a silicide, an oxide or a nitride of the metal of the second barrier layer.

20. The conductor structure of claim 17, further comprising a third barrier layer comprising platinum interposed between the second barrier layer and the gold layer.
